(19) United States
(12) Patent Application Publication
(10) Pub. No.: US 2003/0146434 A1
(43) Pub. Date: Aug. 7, 2003

(54) Semiconductor memory device

(75) Inventor: Hisashi Abo, Tokyo (JP)

Correspondence Address: SUGHRUE MION, PLLC, 2100 Pennsylvania Avenue, NW, Washington, DC, 20037-3213, US

(73) Assignee: ELPIDA MEMORY, INC

(21) Appl. No.: 10/304,853

(22) Filed: Nov. 27, 2002

(30) Foreign Application Priority Data
Nov. 29, 2001 (JP) 364724/2001

(51) Int. Cl. H01L 29/76; H01L 31/036; H01L 29/04

(52) U.S. Cl. 257/67; 257/72

(57) ABSTRACT

To prevent data quality from being deteriorated by reflection from each of memory modules, a semiconductor memory device has a switching circuit located on a mother board in the vicinity of a branching point of the data bus. The switching circuit is controlled by a memory controller to selectively operate the memory modules without substantial reflection from a selected one of the memory modules. To this end, each of the memory modules and the memory controller is terminated with characteristic impedance of the data bus.

### BACKGROUND OF THE INVENTION

The present invention relates to a semiconductor memory device and, more particularly, to a semiconductor memory device capable of high speed operations.

### DESCRIPTION OF THE RELATED ART

In recent years, with an increase of an integration density of semiconductor memories, discussion has been made about operating an interface of these memories at a high speed and a low amplitude of a signal. As a standard for this purpose, an SSTL (Stub Series Termination Logic) has been proposed. Furthermore, to increase an operating speed of a DRAM, which is one of the semiconductor memories, a DDR (Double Data Rate) standard has been also proposed which can double a data rate in operation of the DRAM by synchronizing its data input/output operations with both a leading edge and a trailing edge of each clock signal.

A semiconductor memory device performing these operations has a configuration in which a plurality of memory modules are arranged in parallel with each other with a spacing left therebetween on a mother board. In this configuration, the plurality of memory modules are attached via respective connectors onto the mother board through respective slots formed therein. These slots are each provided with an array of terminals for electrical connection with the respective memory module connectors. On a front side and/or a rear side of the memory module, a plurality of memory units and buffers, such as registers, are attached in such a configuration that these memory units and registers are electrically connected to the connectors through a terminal arranged at each edge of the memory modules.

Furthermore, some of the semiconductor memory devices described above each have a memory controller called a chip set on a mother board to control the memory units on each memory module. In this type of the semiconductor memory device, the memory controller and each of the memory modules are electrically connected with each other through a data bus. In this case, the data bus can be divided into a part wired on the mother board and another part branched off in a comb shape on each memory module from the wired part of the mother board so as to be connected to the memory modules and the memory units. The above-mentioned parts on the mother board and each memory module will be referred to as a board part and a module part, respectively.

A semiconductor memory device of the above-mentioned type is disclosed in U.S. Pat. No. 6,011,710 (hereinafter called Reference 1). Reference 1 points out that, when a data bus in a semiconductor memory device has module parts coming off of a board part, a propagation delay occurs in both the board and the module parts due to capacitive and inductive elements of each of the memory units. Such a propagation delay limits a maximum transmission speed of data propagation. To reduce the capacitive component of the memory units, disclosure is made about a conventional technology of providing FET switches on the data bus on the mother board. The FET switches break the data bus into sections or partial data buses. However, it is pointed out also that this structure cannot avoid an influence of a capacitive component due to inherent capacitance load of the partial data buses.

In order to reduce the capacitive components due to the partial data buses, Reference 1 also discloses about arranging switches on the respective memory modules. In this event, each of the switches is individually turned ON/OFF by a memory controller to selectively couple one of the memory units or devices to or de-couple that memory device from the data bus.

This selective coupling of the memory devices minimizes capacitive loading of the data bus and serves to reduce the capacitive loading on data lines. As a result, this structure is effective to operate the semiconductor memory device at a high speed.

In the semiconductor memory device disclosed in Reference 1, only one of the memory module is connected through the switch to the data bus wired on a mother board, with the other memory modules disconnected from the data bus on the mother board. As a result, this configuration can remove an influence of capacitive components or elements due to the other memory modules.

Herein, it is to be noted in Reference 1 that the switches are arranged on the memory modules and serve to selectively connect, to the data bus, memory devices or units mounted on the respective memory modules through the module parts.

This configuration, however, cannot remove an influence of reflection from a selected memory module. In other words, no consideration is made about the reflection from the selected memory module itself. Furthermore, it has been found out that when data is transmitted or received through the data bus at 100 MHz or more, reflection from the selected memory module has an adverse influence on read/write operations of the data. It has also been found out that such an adverse influence becomes serious more and more on a data signal rather than a clock signal. This is because the data signal varies irregularly as compared with a clock pulse which occurs continually at a constant frequency. Thus, an influence of reflection from each of the memory modules cannot be ignored on the data signal.

In addition, the switches are mounted on the memory modules, namely, memory module substrates in the vicinity of pins formed at edges of each memory module. On designing the memory modules, consideration should be made on each memory module about an impedance that is divided into an impedance between the pins and the switches and another impedance between the switches and the memory units. This makes it difficult to design the memory modules.

### SUMMARY OF THE INVENTION

It is an object of the present invention to provide a semiconductor memory device which can reduce an influence of reflection of data from a memory module.

It is another object of the present invention to provide a semiconductor memory device of the type described, which is capable of data read/write operations at a high speed of 100 MHz or more.

A semiconductor memory device to which the present invention is applicable comprises a plurality of memory modules, a memory controller which controls the memory modules, and a bus which interconnects the memory modules and the memory controller. According to an aspect of the present invention, the semiconductor memory device further comprises a switching circuit which is connected to the bus between the memory controller and the memory modules to selectively put the plurality of the memory modules into a connected state. The bus is branched through the switching circuit into the respective memory modules.

According to another aspect of the present invention, a semiconductor memory device comprises a mother board, a plurality of memory modules attachable to the mother board, a memory controller mounted on the mother board to control the memory modules, and a bus which has a board portion wired on the mother board and module portions wired on the memory modules to interconnect the memory modules and the memory controller. The semiconductor memory device further comprises a switching circuit which is located on the mother board to connect the board portion of the bus to the module portions to selectively put the plurality of the memory modules into a selected state without reflection from the memory module of the selected state.

It is to be noted that that the bus referred to here is an ordinary data bus and also arranged so that impedance of each of the memory modules that is seen from the switching circuit may be substantially equal to the impedance of the memory controller that is seen from the switching circuit. Furthermore, the switching circuit is formed by an FET switch including an NMOS transistor and a PMOS transistor connected in parallel.

### BRIEF DESCRIPTION OF THE DRAWINGS

FIG. 1 is a side view for substantively explaining a configuration of a semiconductor memory device related to one embodiment of the present invention;

FIG. 2 is an equivalent circuit diagram for showing a circuit configuration of the semiconductor memory device of FIG. 1;

FIG. 3 is a circuit diagram for specifically explaining a switching circuit shown in FIG. 2;

FIG. 4 is a block diagram for explaining a memory controller used in the semiconductor memory device shown in FIG. 2; and

FIG. 5 is a block diagram for use in describing a semiconductor memory device according to another embodiment of the present invention.

### DESCRIPTION OF THE PREFERRED EMBODIMENTS

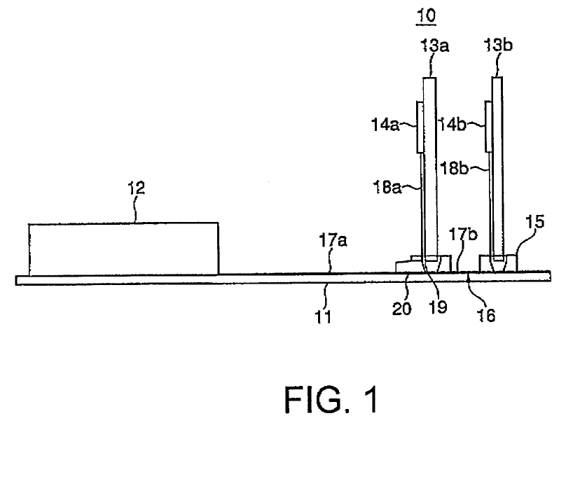

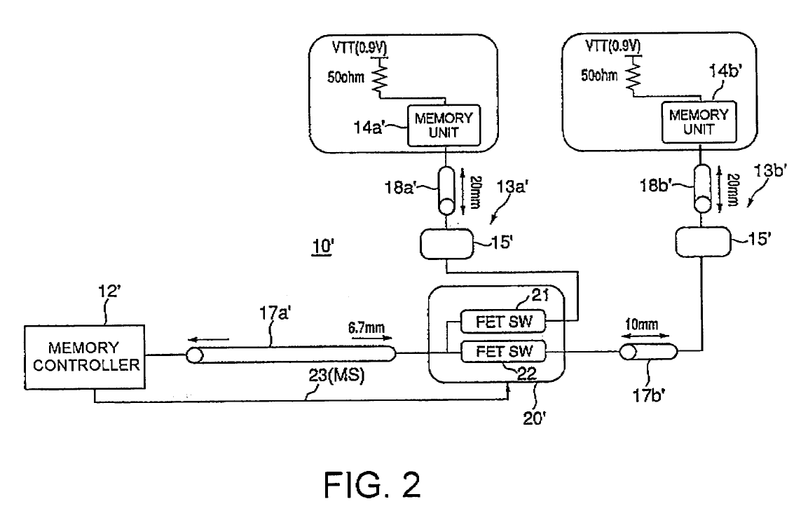

FIG. 1 shows a substantive configuration of a semiconductor memory device 10 according to one embodiment of the present invention and FIG. 2, its equivalent circuit. As shown in FIG. 1, the semiconductor memory device 10 has a mother board 11, a memory controller (chip set) 12 arranged on the mother board 11, and two memory modules 13a and 13b attached on the mother board 11. The illustrated two memory modules 13a and 13b are attached to the mother board 11 via connectors 15 provided on the mother board 11. Memory units 14a and 14b are mounted on selected ones of surfaces of the memory modules 13a and 13b, respectively.

The memory units 14a and 14b on the respective memory modules 13a and 13b are electrically connected with the memory controller 12 through a data bus 16. As shown in the figure, the data bus 16 can be divided into portions (hereinafter called mother-board portions) 17a and 17b wired on the mother board 11 and portions (hereinafter called module portions) 18a and 18b wired on the memory modules 13a and 13b. The module portions 18a and 18b are electrically connected through the connectors 15 to the mother-board portions 17a and 18b, respectively. In other words, it may be considered that each of the module portions 18a and 18b of the data bus 16 branches off from the mother-board portions 17a and 17b. In addition, the mother-board portion 17b and the module portion 18b both of which are connected to the memory module 13b branches off from a common connection point 19 with the data bus 17a.

Furthermore, the semiconductor memory device 10 shown in the figure comprises a switching circuit 20 near the common connection point 19 between the mother-board portions 17a and 17b of the data bus 16. The switching circuit 20 may be located at the common connection point 19. In this example, the switching circuit 20 is directly attached to the mother board 11 as shown in the figure. As can be seen from the figure, the data bus 16 is divided by the switching circuit 20 into the module portion 18a connected to the memory module 13a and a combination of the mother-board portion 17b and the module portion 18b connected to the memory module 13b.

FIG. 2 shows the equivalent circuit of the semiconductor memory device 10 shown in FIG. 1. In FIG.2, elements corresponding to those shown in FIG. 1 are indicated by the same reference numerals with a single quotation mark attached thereto. In the equivalent circuit, a data bus 16′ is expressed in a cylindrical shape because it essentially works as a distributed constant line. In this example, a length of the data bus 16′ between a memory controller 12′ and a switching circuit 20′, that is, a length of a mother-board portion 17a′ is set to 67 mm, while a length of the data bus 16′ between the switching circuit 20′ and a module portion 17b′, that is, a length of a mother-board portion 17b′ is set to 10 mm. Furthermore, in the example shown in FIG. 2, each length of the module portions 18a′ and 18b′ is set to 20 mm. It is to be noted here that memory modules 13a′ and 13b′ are connected through connectors 15′ to the switching circuit 20′ and the mother-board portions 17′b, respectively. The illustrated memory modules 13a′ and 13b′ are featured by the memory units 14a′ and 14b′ terminated with terminating resistors.

In this circuit, resistance of the data bus 16′ can be assumed to be essentially zero. Therefore, the data bus 16′ which serves as a distributed constant line has an impedance represented by a characteristic impedance determined by capacitance and inductance. Furthermore, the memory units 14a′ and 14b′ of the respective memory modules 13a′ and 13b′ are terminated with impedance equal to characteristic impedance (resistance of 50Ω in this case). Moreover, it is assumed that each of circuit constants is set so that impedance of the memory controller 12′ seen from the switching circuit 20′ may also be equal to impedance of each of the memory modules 13a′ and 13b′ seen from the switching circuit 20′. It is also assumed that the memory controller 12′ may be terminated with impedance equal to characteristic impedance.

When either one of the memory modules 13a′ and 13b′ is selected by the switching circuit 20′, the above-mentioned structure makes it possible to reduce, to a negligible level, reflection from the selected memory module 13a′ or 13b′. This is because the selected memory module 13a′ or 13b′ is terminated with the impedance equal to the characteristic impedance. That is, when data is written into the selected one of the memory module 13a′ or 13b′ under control of the memory controller 12′, reflection from the selected memory module 13a′ or 13b′ can be substantially eliminated because they are terminated with characteristic impedance.

On the other hand, when data is read out from the selected memory module 13a′ or 13b′, the data is supplied to the memory controller 12′ without substantial reflection because the memory controller 12′ is also terminated with characteristic impedance.

Therefore, the data can be supplied exactly to a desired device without an adverse influence due to reflection even when a transfer rate becomes high.

The illustrated switching circuit 20′ has a first switch 21 which connects the memory module 13a′ to the data bus 16′ and a second switch 22 which connects the memory module 13b′ to the data bus 16′. Each of the first and the second switches 21 and 22 is constituted of an FET, and is connected to the memory controller 12′ through a control signal line 23. The first switch 21 and the second switch 22 may be arranged in the same circuit or be formed in different switching circuits.

Furthermore, as shown in FIG. 2, the memory controller 12′ supplies a module select signal MS through the control signal line 23 to the switching circuit 20′, so that the memory modules 13a′ and 13b′ are selectively connected to the memory controller 12′ by this module select signal MS. That is, while either the memory module 13a′ or 13b′ is connected to the memory controller 12′, the other memory module 13b′ or 13a′ is disconnected or decoupled from the memory controller 12′. As a result, in this example shown in the figure, the memory controller 12′ is connected with the memory modules 13a′ and 13b′ in a point-to-point relationship.

Although only one data bus 16′ is shown in the figure to simplify it, generally the data bus 16′ is wired in units of eight or sixteen in the form of a plurality of bundles, for example, eight bundles. With this structure, the switching circuit 20′ is provided for each of the data buses 16′.

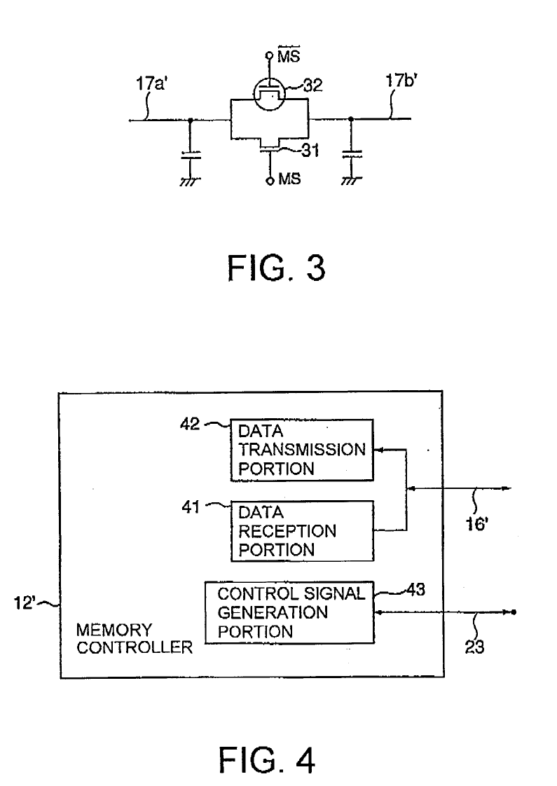

FIG. 3 shows a specific circuit example of the switch 21 or 22 arranged in the switching circuit 20′. As shown in the figure, an NMOS transistor 31 and a PMOS transistor 32 are interconnected in parallel and connected between the mother-board portions 17a′ and 17b′. The module select signal MS is supplied to the gates of both transistors 31 and 32. In FIG. 3, the module select signal MS is given to the gates of the transistors 31 and 32 as control signals which have complimentary polarities of voltage. Specifically, when the ground potential is applied to the gate of the NMOS transistor 31, a potential of 1.8 V is applied to the gate of the PMOS transistor 32. On the other hand, when a potential of 1.8 V is applied to the gate of the NMOS transistor 31, the ground potential is applied to the gate of the PMOS transistor 32. Therefore, when the above-mentioned control signal MS is applied to the switch shown in the figure, both of the NMOS and PMOS transistors 31 and 32 are opened, and, as a result, data transmitted or received through the data bus 16′ is exactly and quickly transferred to the memory controller 12′ or the memory module 13a′ or 13b′.

Referring to FIG. 4, the memory controller 12′ is illustrated which is used in the semiconductor memory device according to the embodiment of the present invention. The illustrated memory controller 12′ has a data transmission portion 41 which transmits data to the data bus 16′, a data reception portion 42 which receives data from the memory module 13a′ or 13b′, and a control signal generator 43 which generates the control signal MS. In this example, the data transmission portion 41 generates a sequence of pulses of 1.8 V, while the control signal generator 43 decides or selects either one of the memory module 13a′ and 13b′, is subject to read/write operations on the basis of an address signal given by a high-order device (not shown). Moreover, the control signal generator 43 supplies the control signal MS to the selected memory module by rendering, into an ON state, only a switch for the selected memory module in the switching circuit 20′.

As a result, the remaining memory module which is not selected by the control signal MS is disconnected from the memory controller 12′ and only the selected memory module is connected to the memory controller 12′. Thus, data is read out from and written into only this selected memory module.

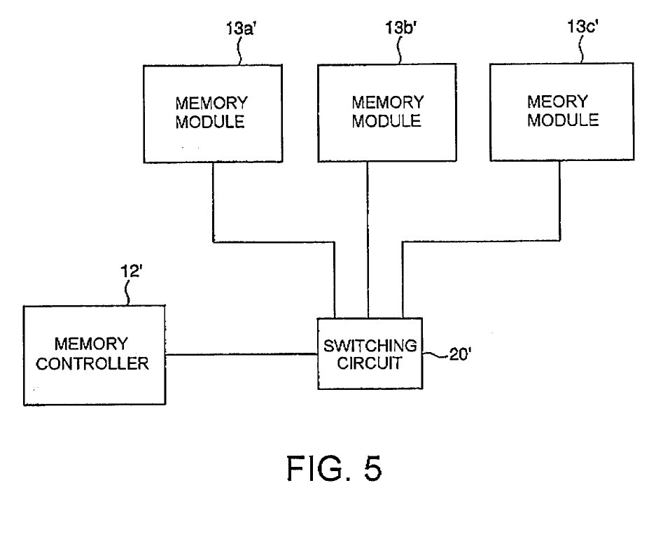

Referring to FIG. 5, illustrated is a semiconductor memory device according to another embodiment of the present invention. The illustrated semiconductor memory device is similar in structure to that shown in FIG. 2 except that three memory modules 13a′, 13b′, and 13c′ are selected by the switching circuit 20a arranged near the common connection point on the data bus 16′. The switching circuit 20a is also arranged on the mother board 11 like the switching circuit 20 illustrated in FIG. 1. The memory modules 13a′, 13b′, and 13c′ are selectively connected to the memory controller 12′ by the control signal MS. In this case, by terminating the memory modules 13a′, 13b′, and 13c′ and the memory controller 12′ with impedance equal to their respective characteristic impedance, an influence of reflection can be reduced to maintain a signal quality like in the case of FIG. 2.

The present invention can provide a semiconductor memory device comprising a plurality of memory modules connected to a data bus in such a configuration that a switching circuit is arranged near or at a point of connecting the plurality of memory modules in common to the data bus. With this structure, the memory modules can be selectively accessed by this switching circuit without any reflection of a signal from the selected memory module. Therefore, it is possible to avoid deterioration of signal quality signal and to realize the semiconductor memory device operated at a high speed.

While the present invention has thus far been described in conjunction with a few embodiments thereof, it will readily be possible for those skilled in the art to put the present invention into practice in various other manners. For example, the memory units may be mounted not only on one surface of each memory module but also on both surfaces of each memory module. The switching circuit 201 may not be restricted to the circuit illustrated in FIG. 3 but may be structured by a wide variety of known switching circuits.

What is claimed is:

1. A semiconductor memory device comprising a plurality of memory modules, a memory controller which controls the memory modules, and a bus for interconnecting the memory modules and the memory controller, the semiconductor memory device further comprising:
a switching circuit which is connected to the bus between the memory controller and the memory modules to selectively put the plurality of the memory modules into a connected state;
the bus being branched through the switching circuit into the respective memory modules.

2. The semiconductor memory device according to claim 1, which is adapted so that impedance of each of the memory modules that is seen from the switching circuit is substantially equal to the impedance of the memory controller that is seen from the switching circuit.

3. The semiconductor memory device according to claim 1, wherein the switching circuit comprises an FET.

4. The semiconductor memory device according to claim 1, wherein the bus is a data bus.

5. The semiconductor memory device according to claim 1, wherein the two memory modules are provided.

6. The semiconductor memory device according to claim 2, wherein each of said memory modules is terminated with impedance substantially equal to characteristic impedance of said data bus.

7. The semiconductor memory device according to claim 6, wherein said memory controller is terminated with impedance substantially equal to characteristic impedance of said data bus.

8. A semiconductor memory device comprising a mother board, a plurality of memory modules attachable to the mother board, a memory controller mounted on the mother board to control the memory modules, and a bus which has a board portion wired on the mother board and module portions wired on the memory modules to interconnect the memory modules and the memory controller, the semiconductor memory device further comprising:
a switching circuit which is located on the mother board to connect the board portion of the bus to the module portions to selectively put the plurality of the memory modules into a selected state without reflection from the memory module of the selected state.

9. The semiconductor memory device according to claim 8, wherein the board portion of the bus has predetermined characteristic impedance while each of the memory modules and the memory controller is terminated with an impedance that is substantially equal to the predetermined characteristic impedance.

10. The semiconductor memory device according to claim 9, wherein the memory modules are equal in number to two or thee.

11. The semiconductor memory device according to claim 10, wherein the switching circuit is structured by a switch including an NMOS transistor and a PMOS transistor connected in parallel between the board portion of the bus.

12. The semiconductor memory device according to claim 11, wherein the NMOS and the PMOS transistors have gates connected to the memory controller.
